(19) United States
(12) Patent Application Publication
(10) Pub. No.: US 2008/0007361 A1
(43) Pub. Date: Jan. 10, 2008

(54) Oscillator with Voltage Drop Generator

(75) Inventor: Chia-Huang Fu, Taipei City (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: MEDIATEK INC., Hsin-Chu (TW)

(21) Appl. No.: 11/668,067

(22) Filed: Jan. 29, 2007

Related U.S. Application Data
(60) Provisional application No. 60/806,535, filed on Jul. 4, 2006.

(51) Int. Cl. H03B 5/08

(52) U.S. Cl. 331/167

(57) ABSTRACT

An oscillator, comprising an LC tank circuit and a negative resistance circuit. The negative resistance circuit is coupled to the LC tank circuit and comprises a pair of transistors and a pair of voltage drop generators. The transistors have first terminals and second terminals, wherein the first terminals are cross-coupled to the second terminals thereof. The voltage drop generators are respectively coupled between the first and second terminals of the transistors.

This application claims the benefit of U.S. Provisional Application No. 60/806,535, filed on Jul. 4, 2006.

### BACKGROUND OF THE INVENTION

1. Field of the Invention

The invention relates to a voltage controlled oscillator (VCO) and, in particular, to a VCO with voltage drop generators improving output swing thereof.

2. Description of the Related Art

FIG. 1A is a circuit diagram of a basic voltage controlled oscillator (VCO) 100 comprising an LC tank 110, negative resistance circuits 120 and 130, and a current source 140. The negative resistance circuits 120 and 130 respectively comprise cross-coupled bipolar junction transistors (BJTs) and metal-oxide-semiconductor (MOS) transistors. Collectors C1 and C2 of the BJTs Q1 and Q2 of the negative resistance circuit 120 are coupled to the LC tank 110, as are the drains of the MOS transistors of the negative resistance circuit 130. The emitters of the BJTs are grounded and sources of the MOS transistors are coupled to the current source 140.

FIGS. 1B and 1C respectively show output waveforms of the collectors C1 and C2 of the BJTs Q1 and Q2 in FIG. 1A under low frequency and high frequency, while the waveforms also respectively represent the base nodes of the BJT Q2 and Q1. The low frequency and high frequency respectively correspond to small output swing and large output swing of the collectors C1 and C2 of the BJTs Q1 and Q2. It is known that a BJT enters saturation mode when V_{BE}>0.7V and V_{BC}>0.5V, wherein V_{BE} is a voltage difference between a base and an emitter of the BJT and V_{BC} a voltage difference between the base and collector thereof. As a result, the BJTs may enter a saturation mode when output swing at the collectors C1 and C2 is large. For example, the BJT Q2 enters the saturation mode when V_{C1C2}=0.5V as shown in FIG. 1C. When either of BJTs enters the saturation mode, the VCO would not work normally. On the other hand, the output swing is limited to a certain range in order to prevent the aforementioned BJT entering saturation mode.

FIG. 2A is a circuit diagram of a conventional voltage controlled oscillator (VCO) 200 with RC circuits. The VCO 200 in FIG. 2A is similar to that in FIG. 1A. The only difference is that the negative resistance circuit 220 of the VCO 200 further comprises RC circuits 225. The RC circuits 225 comprise a first capacitor C3 connected between the collector C1 of the BJT Q1 and the base B2 of the BJT Q2 and a second capacitor C4 connected between the base B1 of the BJT Q1 and the collector C2 of the BJT Q2. In addition, the RC circuits 225 further comprise a first resistor R1 and a second resistor R2 with one end thereof respectively coupled to the base B2 of the second BJT Q2 and the base B1 of the first BJT Q1 and the other ends commonly connected to a bias source Bias.

FIG. 2B shows output waveforms of the collectors C1 and C2 of the BJTs Q1 and Q2 in FIG. 2A under high frequency. The high frequency corresponds to large output swing of the collectors C1 and C2 of the BJTs Q1 and Q2. To some extent, voltage of the base B2 tracks that of the collector C1. In addition, the bias source Bias typically provides a constant bias voltage to the RC circuits 225. As a result, the BJTs can still enter a saturation mode when output swing at the collectors C1 and C2 is large. For example, the BJT Q2 enters the saturation mode when V_{B2C2}=0.5V as shown in FIG. 2B. When either of the BJTs enters the saturation mode, the VCO would not work normally.

### BRIEF SUMMARY OF THE INVENTION

An embodiment of an oscillator comprises an LC tank circuit and a negative resistance circuit. The negative resistance circuit is coupled to the LC tank circuit and comprises a pair of transistors and a pair of voltage drop generators. The transistors have first terminals and second terminals, wherein the first terminals are cross-coupled to the second terminals thereof. The voltage drop generators are respectively coupled between the first and second terminals of the transistors.

An embodiment of a method of oscillation of a negative resistance circuit comprises providing a pair of transistors having first terminals and second terminals, wherein the first terminals are cross-coupled to the second terminals thereof, inserting a voltage drop generator respectively coupled between the first and second terminals of the transistors, and generating voltage drops across the first and second terminals of the transistors.

An embodiment of a negative resistance circuit comprises a pair of transistors and a pair of voltage drop generators. The transistors have first terminals and second terminals, wherein the first terminals are cross-coupled to the second terminals thereof. The voltage drop generators are respectively coupled between the first and second terminals of the transistors.

A voltage controlled oscillator (VCO) with voltage drop generators is disclosed. The voltage drop generators keep a voltage difference between cross-coupled bases and collectors such that the cross-coupled BJTs do not enter a saturation mode. As a result, the VCO does not malfunction due to cross-coupled BJTs in the saturation mode.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A is a circuit diagram of a basic voltage controlled oscillator (VCO) 100 comprising an LC tank 110, negative resistance circuits 120 and 130, and a current source 140;

FIGS. 1B and 1C respectively show output waveforms of the collectors C1 and C2 of the BJTs Q1 and Q2 in FIG. 1A under low frequency and high frequency;

FIG. 2A is a circuit diagram of a conventional voltage controlled oscillator (VCO) 200 with RC circuits;

FIG. 2B shows output waveforms of the collectors C1 and C2 of the BJTs Q1 and Q2, and that of the base B2 of the BJT Q2 in FIG. 2A under high frequency;

FIG. 3A is a circuit diagram of a voltage controlled oscillator (VCO) with voltage drop generators according to an embodiment of the invention;

FIGS. 3B and 3C respectively show output waveforms of the collectors C3 and C4 of the BJTs Q3 and Q4, and that of the base B4 of the BJT Q4 in FIG. 3A under low frequency and high frequency;

FIG. 4 is a schematic diagram of a counterpart of the negative resistance circuit 300 in FIG. 3A;

FIG. 5 is a circuit diagram of a voltage controlled oscillator (VCO) with voltage drop generators according to an embodiment of the invention;

FIG. 6 is a circuit diagram of a voltage controlled oscillator (VCO) with voltage drop generators according to another embodiment of the invention;

FIG. 7 is a circuit diagram of a voltage controlled oscillator (VCO) with voltage drop generators according to yet another embodiment of the invention; and

FIG. 8 is a circuit diagram of a voltage controlled oscillator (VCO) with voltage drop generators according to another embodiment of the invention.

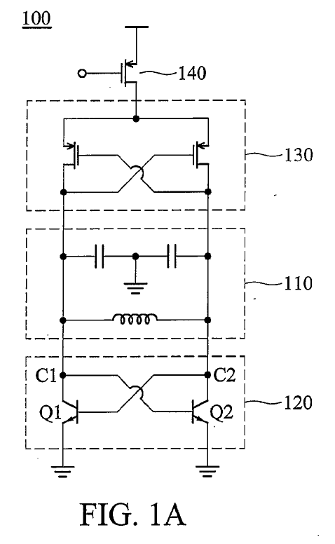

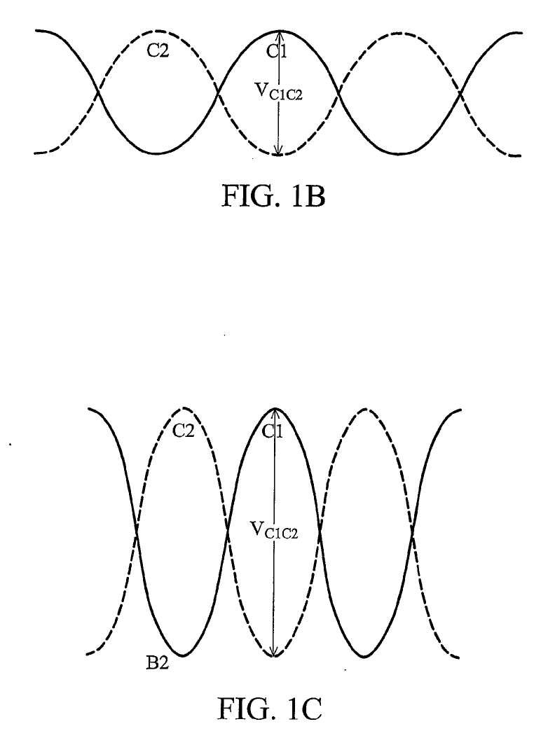

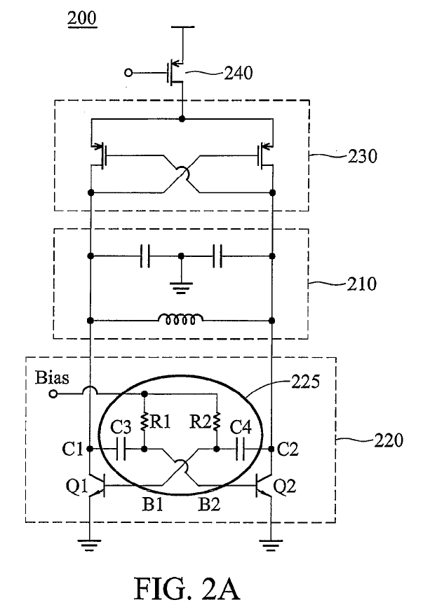

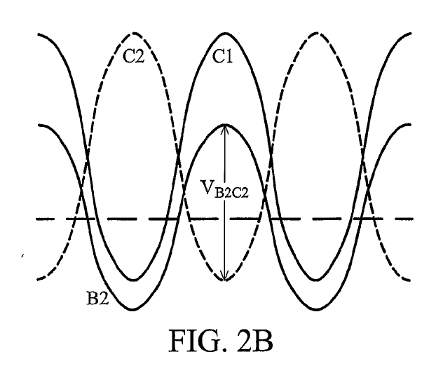

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

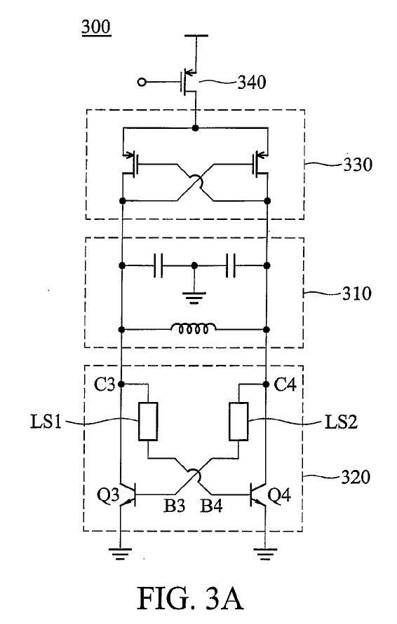

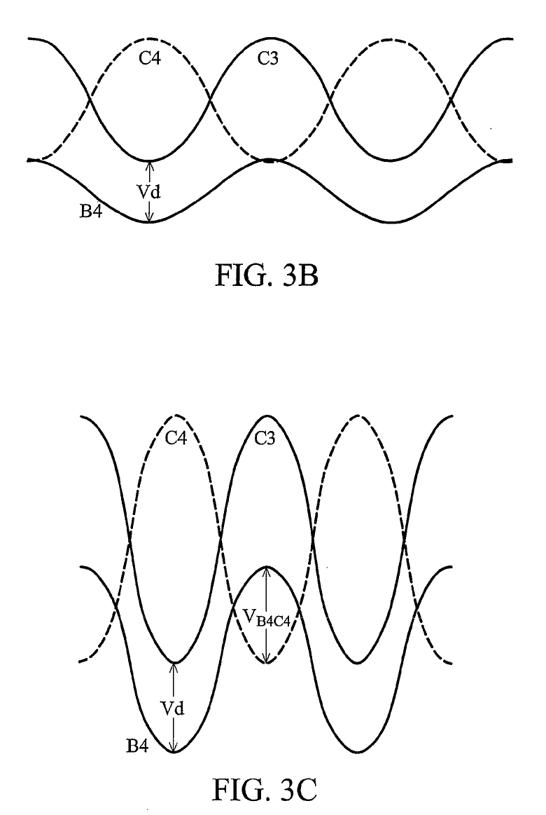

FIG. 3A is a circuit diagram of a voltage controlled oscillator (VCO) with voltage drop generators according to an embodiment of the invention. The voltage controlled oscillator (VCO) 300 comprises an LC tank 310, negative resistance circuits 320 and 330, and a current source 340. The negative resistance circuits 320 and 330 respectively comprise cross-coupled NPN bipolar junction transistors (BJTs) and metal-oxide-semiconductor (MOS) transistors. Collectors C3 and C4 of the NPN BJTs Q3 and Q4 of the negative resistance circuit 320 are coupled to the LC tank 310, as are the drains of the MOS transistors of the negative resistance circuit 330. In FIG. 3A, the emitters of the NPN BJTs are grounded and the sources of the MOS transistors are coupled to a supply voltage via the current source 340. It is noted that the emitters of the NPN BJTs are not necessarily coupled to ground, and the sources of MOS transistors are not necessarily coupled to a supply voltage via a current source. The emitters of the NPN BJTs can also be coupled to a common node directly or indirectly via a current source or degeneration devices. The sources of the MOS transistors can also be coupled to a common node directly or indirectly via a current source or degeneration devices. The degeneration devices could be resistors, capacitors, inductors or their combinations with or without active transistors.

Referring to FIG. 3A, a first voltage drop generator LS1 is coupled between the collector C3 of the NPN BJT Q3 and a base B4 of the NPN BJT Q4 and a second voltage drop generator LS2 coupled between the collector C4 of the NPN BJT Q4 and a base B3 of the NPN BJT Q3. Due to the voltage drop generator LS1, voltage of the collector C3 exceeds the base B4 by a voltage no matter how large the output swing. Similarly, voltage of the collector C4 exceeds the base B3 by a voltage due to the voltage drop generator LS2.

FIGS. 3B and 3C respectively show output waveforms of the collectors C3 and C4 of the BJTs Q3 and Q4, and that of the base B4 of the BJT Q4 in FIG. 3A under low frequency and high frequency. As shown in FIG. 3C, since voltage of the collector C3 exceeds the base B4 by a voltage Vd, voltage level of the collector C4 is lifted higher with respect to the base B4. In other words, the voltage difference V_{B4C4} between the base B4 and the collector C4 is not so large when voltage level of the base B4 is at a peak thereof and that of the collector C4 is at a valley thereof. As a result, V_{B4C4} is kept lower than 0.5V and the BJT Q4 does not enter a saturation mode, nor does the BJT Q3. Thus, the VCO 300 works normally even when output swing thereof is very large.

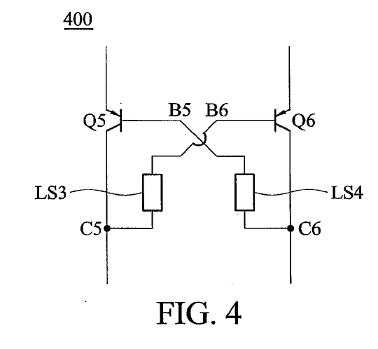

FIG. 4 is a schematic diagram of a counterpart of the negative resistance circuit 320 in FIG. 3A. The BJTs Q5 and Q6 of the negative resistance circuit 400 in FIG. 4 are PNP BJTS. Voltage drop generators LS3 and LS4 are inserted between the cross-coupled bases B5 and B6 and collectors C5 and C6. As a result, voltage of the base B5 exceeds the collector C6 by a voltage due to the voltage drop generator LS4 and that of the base B6 exceeds the collector C5 by a voltage due to the voltage drop generator LS3. The negative resistance circuit 400 in FIG. 4 can be used on a supply voltage side of a VCO according to an embodiment of the invention.

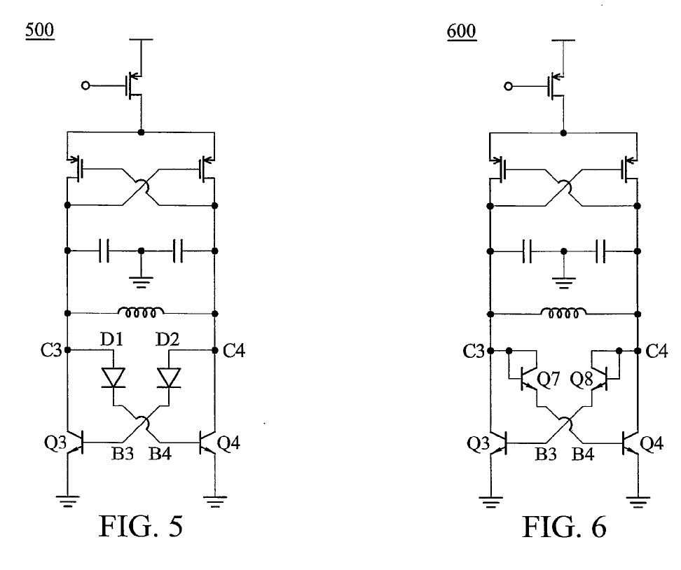

FIG. 5 is a circuit diagram of a voltage controlled oscillator (VCO) with voltage drop generators according to an embodiment of the invention. The VCO 500 in FIG. 5 is similar to that in FIG. 3A. The only difference is that the voltage drop generators LS1 and LS2 in the negative circuit 320 in FIG. 3A are replaced by diodes D1 and D2 as shown in FIG. 5. In FIG. 5, anodes of the diodes D1 and D2 are connected to the collectors C3 and C4 and cathodes thereof connected to the bases B4 and B3. As result, the NPN BJTs Q3 and Q4 would not enter a saturation mode. Output swing of the VCO 500 is thus improved.

FIG. 6 is a circuit diagram of a voltage controlled oscillator (VCO) with voltage drop generators according to another embodiment of the invention. The VCO 600 in FIG. 6 is similar to that in FIG. 3A. The only difference is that the voltage drop generators LS1 and LS2 in the negative circuit 320 in FIG. 3A are replaced by NPN bipolar junction transistors (BJTs) Q7 and Q8 as shown in FIG. 6. In FIG. 6, bases and collectors of the NPN BJTs Q7 and Q8 are commonly connected to the collectors C3 and C4 and emitters thereof connected to the bases B4 and B3. As result, the NPN BJTs Q3 and Q4 would not enter a saturation mode. Output swing of the VCO 600 is thus improved.

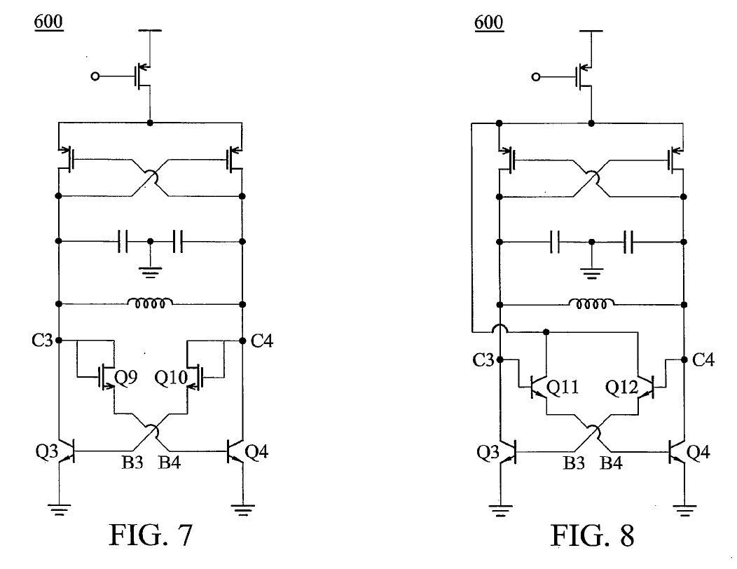

FIG. 7 is a circuit diagram of a voltage controlled oscillator (VCO) with voltage drop generators according to yet another embodiment of the invention. The VCO 700 in FIG. 7 is similar to that in FIG. 3A. The only difference is that the voltage drop generators LS1 and LS2 in the negative circuit 320 in FIG. 3A are replaced by metal-oxide-semiconductor (MOS) transistors Q9 and Q10 as shown in FIG. 7. In FIG. 7, gates and drains of the MOS transistors Q9 and Q10 are commonly connected to the collectors C3 and C4 and sources thereof connected to the bases B3 and B4. As result, the NPN BJTs Q3 and Q4 would not enter a saturation mode. Output swing of the VCO 700 is thus improved.

FIG. 8 is a circuit diagram of a voltage controlled oscillator (VCO) with voltage drop generators according to another embodiment of the invention. The VCO 800 in FIG. 8 is similar to that in FIG. 3A. The only difference is that the voltage drop generators LS1 and LS2 in the negative circuit 320 in FIG. 3A are replaced by NPN bipolar junction transistors (BJTs) Q11 and Q12 as shown in FIG. 8. In FIG. 8, bases of the NPN BJTs Q11 and Q12 are respectively connected to the collectors C3 and C4, emitters thereof respectively connected to the bases B4 and B3, and collectors commonly connected to sources of the cross-coupled MOS transistors. As result, the NPN BJTs Q3 and Q4 would not enter a saturation mode. Output swing of the VCO 800 is thus improved. It is noted that the collectors of the NPN BJTs Q11 and Q12 are not necessarily commonly connected to sources of the cross-coupled MOS transistors. As long as the collectors of the NPN BJTs Q11 and Q12 are connected to a bias voltage which exceeds voltages of the bases thereof, output swing of the VCO 800 can thus be improved

A voltage controlled oscillator (VCO) with voltage drop generators is disclosed. The voltage drop generators keep a voltage difference between cross-coupled bases and collectors such that the cross-coupled BJTs do not enter a saturation mode. As a result, the VCO does not malfunction due to cross-coupled BJTs in the saturation mode.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An oscillator, comprising:
an LC tank circuit; and
a negative resistance circuit, coupled to the LC tank circuit, comprising:
a pair of transistors having first terminals and second terminals, wherein the first terminals are cross-coupled to the second terminals thereof; and
a pair of voltage drop generators respectively coupled between the first and second terminals of the transistors.

2. The oscillator as claimed in claim 1, wherein the transistors have third terminals coupled to a common node directly or indirectly.

3. The oscillator as claimed in claim 1, wherein the transistors are bipolar junction transistors (BJT) and the first, second, and third terminals are respectively bases, collectors, and emitters.

4. The oscillator as claimed in claim 1, wherein the voltage drop generators are diodes, bipolar junction transistors (BJTs) or metal-oxide-semiconductor (MOS) transistors.

5. The oscillator as claimed in claim 1, wherein the voltage drop generators are bipolar junction transistors (BJTs) with bases and collectors thereof commonly connected.

6. The oscillator as claimed in claim 1, wherein the voltage drop generators are metal-oxide-semiconductor (MOS) transistors with gates and drains thereof commonly connected.

7. The oscillator as claimed in claim 1, wherein the voltage drop generators are BJTs with emitters and bases thereof respectively connected to the first and second terminals of the transistors, and collectors commonly connected to a bias voltage which exceeds voltages of the bases.

8. A method of oscillation of a negative resistance circuit, comprising:
providing a pair of transistors having first terminals and second terminals, wherein the first terminals are cross-coupled to the second terminals thereof;
inserting a voltage drop generator respectively coupled between the first and second terminals of the transistors; and
generating voltage drops across the first and second terminals of the transistors.

9. The method as claimed in claim 8, wherein the voltage drop generators are diodes or bipolar junction transistors (BJTs) or metal-oxide-semiconductor (MOS) transistors.

10. The method as claimed in claim 8, wherein the voltage drop generators are bipolar junction transistors (BJTs) with bases and collectors thereof commonly connected.

11. The method as claimed in claim 8, wherein the voltage drop generators are metal-oxide-semiconductor (MOS) transistors with gates and drains thereof commonly connected.

12. The method as claimed in claim 8, wherein the voltage drop generators are BJTs with emitters and bases thereof respectively connected to the first and second terminals of the transistors, and collectors commonly connected to a bias voltage which is higher than voltages of the bases.

13. A negative resistance circuit, comprising:
a pair of transistors having first terminals and second terminals, wherein the first terminals are cross-coupled to the second terminals thereof; and
a pair of voltage drop generators respectively coupled between the first and second terminals of the transistors.

14. The negative resistance circuit as claimed in claim 13, wherein the transistors having third terminals coupled to a common node directly or indirectly.

15. The negative resistance circuit as claimed in claim 13, wherein the transistors are bipolar junction transistors (BJT) and the first, second, and third terminals are respectively bases, collectors and emitters.

16. The negative resistance circuit as claimed in claim 13, wherein the voltage drop generators are diodes, bipolar junction transistors (BJTs) or metal-oxide-semiconductor (MOS) transistors.

17. The negative resistance circuit as claimed in claim 13, wherein the voltage drop generators are bipolar junction transistors (BJTs) with bases and collectors thereof commonly connected.

18. The negative resistance circuit as claimed in claim 13, wherein the voltage drop generators are metal-oxide-semiconductor (MOS) transistors with gates and drains thereof commonly connected.

19. The negative resistance circuit as claimed in claim 13, wherein the voltage drop generators are BJTs with emitters and bases thereof respectively connected to the first and second terminals of the transistors, and collectors commonly connected to a bias voltage which is higher than voltages of the bases.
